(19) United States
(12) Patent Application Publication
(10) Pub. No.: US 2010/0133582 A1
(43) Pub. Date: Jun. 3, 2010

(54) NITRIDE SEMICONDUCTOR LIGHT EMITTING DEVICE

(76) Inventors: Atsunori MOCHIDA, Osaka (JP); Kouji Makita, Hyogo (JP)

Correspondence Address: MCDERMOTT WILL & EMERY LLP, 600 13TH STREET, NW, WASHINGTON, DC, 20005-3096, US

(21) Appl. No.: 12/555,464

(22) Filed: Sep. 8, 2009

(30) Foreign Application Priority Data
Dec. 3, 2008 (JP) 2008-309090

(51) Int. Cl. H01L 33/00

(52) U.S. Cl. 257/103; 257/E33.06

(57) ABSTRACT

A nitride semiconductor light emitting device includes: a multilayer structure a plurality of nitride semiconductor layers including a light emitting layer where the multilayer structure has cavity facets facing each other; and a plurality of protective films made of dielectric materials on at least one of the cavity facets. Among the plurality of protective films, a first protective film in contact with the cavity facet is made of a material containing no oxygen. A second protective film on a surface of the first protective film opposite to the cavity facet is made of a material containing aluminum lower in crystallization temperature than the first protective film. A third protective film on a surface of the second protective film opposite to the first protective film has an exposed surface and made of a material higher in crystallization temperature than the second protective film.

### CROSS-REFERENCE TO RELATED APPLICATION

This application claims priority to Japanese Patent Application No. 2008-309090 filed on Dec. 3, 2008, the disclosure of which including the specification, the drawings, and the claims is hereby incorporated by reference in its entirety.

### BACKGROUND OF THE INVENTION

The present disclosure relates to nitride semiconductor light emitting devices, and specifically to nitride semiconductor light emitting devices including cavity facets provided with protective films.

### DESCRIPTION OF THE PRIOR ART

In recent years, as light sources for optical disk apparatuses, a variety of semiconductor light emitting devices is widely used. Especially, blue-violet semiconductor light emitting devices using group III-V nitride semiconductors such as gallium nitride (GaN) emit light in the short wavelength region (e.g., the 400 nm band) in which the diameter of a light gathering spot on an optical disk can be smaller compared to light in the red region or the infrared region, and effectively improve reproducing the optical disk or recording density of the optical disk. Thus, such blue-violet semiconductor light emitting devices have become popular and indispensable as light sources for next-generation high-density optical disks (for example, Blu-ray Discs (registered trademark)).

Optical disks using blue-violet semiconductor light emitting devices require highly reliable, high-power, blue-violet semiconductor laser devices to allow higher density and high-speed writing. In aluminum gallium arsenide (AlGaAs)-based, or aluminum gallium indium phosphide (AlGaInP)-based, conventional semiconductor laser devices used for Compact Discs (CDs) and Digital Versatile Discs (DVDs), dielectric films made of oxide are formed as protective films on cavity facets in order to prevent deterioration of and Catastrophic Optical Damage (COD) to the cavity facets.

However, if, in blue-violet GaN-based laser devices, facet protective films made of oxide are formed on cavity facets, oxygen in the facet protective films or in the atmosphere oxidizes the cavity facets or adhesion layers, which causes deterioration of the semiconductor laser devices.

With respect to facet protective films of blue-violet GaN-based laser devices, for example, Japanese Unexamined Patent Publication No. 2007-103814 (hereinafter, referred to as Patent Document 1) describes the approach of providing a layer made of aluminum nitride (AlN) as a facet protective film to separate a facet from oxygen for reducing deterioration of the facet caused by oxidation.

Moreover, for example, Japanese Unexamined Patent Publication No. 2008-218523 (hereinafter referred to as Patent Document 2) describes the approach of forming facet protective films respectively of an aluminum nitride film having a crystal structure and a silicon dioxide (SiO₂) film having an amorphous structure to suppress the occurrence of cracks and to increase the COD level.

Furthermore, for example, Japanese Unexamined Patent Publication No. 2007-318088 (hereinafter referred to as Patent Document 3) describes the approach of providing a configuration including facet protective films respectively made of aluminum nitride, aluminum oxide (Al₂O₃), silicon dioxide, and aluminum oxide in this order from a facet side to achieve a facet reflectance of 18% or higher at a light emitting section and to achieve a reduced threshold current. Since in this approach, a first protective film is made of aluminum nitride, it is also possible to reduce deterioration of a facet caused by oxidation and to realize a high COD level.

To stably operate blue-violet GaN-based light emitting devices at a high power level, it is required to form stable facet protective films which reduce light absorption on cavity facets caused by non-radiative recombination and are capable of resisting high optical outputs.

### SUMMARY OF THE INVENTION

However, the above-mentioned conventional nitride semiconductor light emitting devices may have disadvantages as follows.

With the protective film made of AlN described in Patent Document 1, the disadvantage of facet oxidation can be improved, and the COD level and the reliability can be increased. However, using Al₂O₃ for a second protective film may result in crystallization of Al₂O₃ in the second protective film at its interface to the atmosphere after long-hour operation of a laser device, which may impair stable laser operation.

Since the facet protective films described in Patent Document 2 are respectively made of AlN and SiO₂, the disadvantage of facet oxidation can be improved, and the COD level can be increased. However, since the AlN film and the SiO₂ film are in contact with each other, a compressive stress in the same direction may be caused, which may results in rapid deterioration during operation of a laser device.

Moreover, since the facet protective films described in Patent Document 3 are respectively made of AlN, Al₂O₃, SiO₂, and Al₂O₃, the facet reflectance of 18% or higher at the light emitting section can be achieved to reduce the threshold current. However, since an outer protective film in contact with the outside air is the Al₂O₃ film, the Al₂O₃ film may be crystallized at its interface to the atmosphere during operation of a laser device. Moreover, the facet reflectance of 18% or higher may increase the optical density of a cavity facet of the light emitting section, thereby lowering the COD level.

In view of the problems discussed above, the present invention may be capable of increasing the COD level and providing long-term reliability during high-power operation of nitride semiconductor light emitting devices.

For this purpose, in the present invention, a nitride semiconductor light emitting device includes a plurality of facet protective films, among which an outer protective film in contact with the outside air is made of a material of highest crystallization temperature.

Specifically, an example nitride semiconductor light emitting device according to the present invention includes: a multilayer structure composed of a plurality of nitride semiconductor layers including a light emitting layer where the multilayer structure has cavity facets facing each other; and a plurality of protective films made of dielectric materials on at least one of the cavity facets, wherein among the plurality of protective films, a first protective film in contact with the cavity facet is made of a material containing no oxygen, a second protective film on a surface of the first protective film opposite to the cavity facet is made of a material containing aluminum lower in crystallization temperature than the first protective film, and a third protective film on a surface of the second protective film opposite to the first protective film has an exposed surface and is made of a material higher in crystallization temperature than the second protective film.

With the example nitride semiconductor light emitting device according to the present invention, it is possible to suppress alteration in the protective films caused by long-hour irradiation with a high-energy, blue-violet laser beam and to prevent changes of laser characteristics caused by the alteration in the protective films. Moreover, the first protective film made of a material containing no oxygen suppresses permeation of oxygen from the facet protective films and the atmosphere to the cavity facet during operation of the light emitting device, thereby allowing deterioration of the cavity facet to be reduced.

In the example nitride semiconductor light emitting device of the present invention, the third protective film may be composed of two or more films respectively made of different materials.

In this configuration, a material of high crystallization temperature is used for an outermost surface layer in contact with the outside air to enable materials for other layers to be selected freely. Therefore, the reflectance can be adjusted easily.

In the example nitride semiconductor light emitting device of the present invention, the crystallization temperature of a surface portion of the third protective film may be 1000° C. or higher.

With this configuration, it is possible to prevent alteration in the third protective film at an outermost surface serving as an interface to the atmosphere, and to prevent changes of the laser characteristics caused by the alteration in the protective film after operation of the light emitting device, for example, long-hour irradiation with a high-energy, blue-violet laser beam.

In the example nitride semiconductor light emitting device of the present invention, the plurality of protective films may be formed on both of the cavity facets.

With this configuration, it is possible to suppress alteration in the protective films on the cavity facets, and to prevent changes of the laser characteristics caused by the alteration of the protective films. Moreover, providing films containing no oxygen as first protective films makes it possible to suppress permeation of oxygen to the cavity facets and deterioration of the cavity facets.

In the example nitride semiconductor light emitting device of the present invention, the third protective film may be made of silicon dioxide.

According to this configuration, the third protective film has a high crystallization temperature and is lower in refractive index than the second protective film containing aluminum. Therefore, it is possible to prevent alteration in the third protective film at the outermost surface serving as the interface to the atmosphere and to prevent changes of the laser characteristics caused by the alteration in the protective film even during operation of the light emitting device, for example, long-hour irradiation with a high-energy, blue-violet laser beam. Moreover, the facet reflectance can be set to less than 18% stably with respect to variations in film thickness.

In the example nitride semiconductor light emitting device of the present invention, the second protective film may be made of aluminum oxide.

With this configuration, it is possible to dissipate heat concentrating on the cavity facet through the facet protective films, since the aluminum oxide has a good thermal conductivity. Therefore, it is possible to suppress a reduction in the facet breaking level during operation of the light emitting device.

In the example nitride semiconductor light emitting device of the present invention, the first protective film may be made of aluminum nitride.

With this configuration, it is possible to suppress permeation of oxygen from the facet protective films and the atmosphere to the cavity facet during operation of the light emitting device and to reduce deterioration of the cavity facet. Moreover, forming an aluminum nitride film in contact with the cavity facet makes it possible to suppress alteration in a portion of the second protective film close to the cavity facet.

In this case, the first protective film has a crystal plane whose crystallographic axes form an angle of 90 degrees with crystallographic axes of a crystal plane of the cavity facet having the first protective film formed thereon.

With this configuration, the protective film can have a dense structure, thereby suppressing permeation of oxygen during operation of the light emitting device. Therefore, it is possible to reduce deterioration of the cavity facet.

Furthermore, in this case, an extinction coefficient of the aluminum nitride may be 0.005 or less in an oscillation wavelength band of emitted light output from the light emitting layer.

With this configuration, it is possible to reduce absorption of light caused by the facet protective films at a light emitting section. Therefore, the COD level can be increased, and reduction in the COD level during operation of the light emitting device can be suppressed.

Moreover, in this case, the film thickness of the aluminum nitride may be greater than or equal to 4 nm and less than or equal to 20 nm. Forming the aluminum nitride film serving as the first protective film to have a thickness of 4 nm or more makes it possible to suppress variations in oxygen permeability at a cavity facet section caused by variations of the film thickness of the aluminum nitride, and in particular to suppress variations in the COD level. Moreover, forming the aluminum nitride film to have a thickness of 20 nm or less makes it possible to reduce absorption of a laser beam caused by the aluminum nitride film due to its extinction coefficient, and to achieve a less reduction in the COD level during operation of the laser device compared to the case of a large film thickness.

In the example nitride semiconductor light emitting device of the present invention, the reflectance of the plurality of protective films may be less than 18%. With this configuration, it is possible to set the reflectance to less than 18%, which is the reflectance in a state without the protective films. Therefore, the optical density at the cavity facet of the light emitting section can be small.

Alternatively, in the nitride semiconductor light emitting device of the present invention, the reflectance of the plurality of protective films may be greater than or equal to 8% and less than 13%.

Thus, when the facet reflectance is 8% or more, it is possible to suppress degradation of noise characteristics. Moreover, when the facet reflectance is less than 13%, the optical density at a facet section of the light emitting section can be small.

As described above, with the example nitride semiconductor light emitting device according to the present invention, it is possible to suppress crystallization of the second protective film containing aluminum of low crystallization temperature, and to suppress permeation of oxygen to the cavity facet of the light emitting section. As a result, it is possible to suppress deterioration of a laser cavity facet and occurrence of the COD at a low level, thereby providing long-term reliability during high-power operation of the laser device.

### BRIEF DESCRIPTION OF THE DRAWINGS

FIG. 1 is a cross section showing a schematic configuration in a direction perpendicular to a direction of a cavity of a nitride semiconductor light emitting device according to first through third example embodiments.

FIG. 2 is a cross section showing a schematic configuration of an ECR sputtering apparatus.

FIG. 3 is a cross section showing a schematic configuration of the nitride semiconductor light emitting device according to the first example embodiment in a direction parallel to the direction of its cavity.

FIG. 4 is a cross section showing a schematic configuration in a direction parallel to a direction of a cavity of a conventional nitride semiconductor light emitting device after long-hour operation of the light emitting device.

FIG. 5 is a graph showing the oscillation wavelength dependence of the facet reflectance according to the first example embodiment in a graph showing the relationship between the facet reflectance and variation in film thickness.

FIG. 6 is a graph showing the relationship between the relative intensity noise (RIN) and the front facet reflectance.

FIG. 7 is a graph showing the relationship between the kink level and the front facet reflectance.

FIG. 8 is a graph showing the relationship between the extinction coefficient of a first protective film and a reduction in COD level according to the first example embodiment.

FIG. 9 is a graph showing the relationship between the N₂ partial pressure for depositing an AlN film serving as the first protective film and film deposition rate according to first through third example embodiments.

FIG. 10 is a cross section showing a schematic configuration in a direction parallel to the direction of a cavity of the nitride semiconductor light emitting device according to the second example embodiment.

FIG. 11 is a cross section showing a schematic configuration in a direction parallel to the direction of a cavity of the nitride semiconductor light emitting device according to the third example embodiment.

### DESCRIPTION OF THE PREFERRED EMBODIMENTS

### First Example Embodiment

A first example embodiment will be described with reference to the drawings.

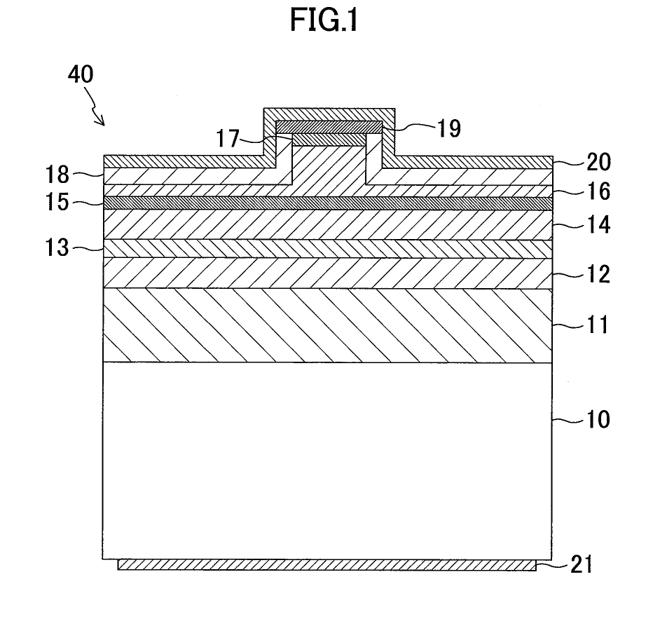

FIG. 1 shows a cross-sectional configuration in a direction perpendicular to a direction of a cavity of a nitride semiconductor light emitting device according to the first example embodiment.

As shown in FIG. 1, the nitride semiconductor light emitting device according to the first example embodiment is formed on a principal surface of an n-type substrate 10 made of n-type GaN having a thickness of about 80 μm. An n-type cladding layer 11 made of n-type AlGaN having a thickness of 1.5 μm, an n-type light guide layer 12 made of n-type GaN having a thickness of 0.016 μm, a multi-quantum well active layer 13 made of InGaN and constituted by a well layer having a thickness of 7 nm and a barrier layer having a thickness of 13 nm, a light guide layer 14 made of InGaN having a thickness of 0.06 μm, a p-type light guide layer 15 made of p-type AlGaN having a thickness of 0.1 μm, a p-type cladding layer 16 made of p-type AlGaN having a thickness of 0.5 μm, and a p-type contact layer 17 made of p-type GaN having a thickness of 0.1 μm are sequentially formed. Hereinafter, the semiconductor layers from the n-type cladding layer 11 to the p-type contact layer 17 are referred to as a multilayer structure 40.

It should be noted that the thicknesses described above are mere examples, and the present example embodiment is not limited as such.

Among the layers mentioned above, a portion of the p-type cladding layer 16 and the p-type contact layer 17 are processed into a ridge stripe extending along the direction of the cavity. The width of the ridge stripe is, for example, about 1.4 μm, the length of the cavity is, for example, 800 μm, and the width of a chip is for example 200 μm.

On an upper surface of the ridge stripe, a p-side contact electrode 19 made of palladium (Pd)/platinum (Pt) is formed in contact with the p-type contact layer 17. Moreover, on an upper surface of an exposed portion of the p-type cladding layer 16 excepting the ridge stripe, a dielectric film 18 is formed. On the p-side contact electrode 19 of the ridge stripe and on the dielectric film 18, a p-side wire electrode 20 made of titanium (Ti)/Pt/gold (Au) is formed. Moreover, on a back surface of the substrate 10, an n-side contact electrode 21 made of Ti/Pt/Au is formed.

Hereinafter, descriptions are given of a method for fabricating a nitride semiconductor laser device of the first example embodiment.

First, a multilayer structure 40 constituting the nitride semiconductor light emitting device is formed on a principal surface of an n-type substrate 10 by metal-organic chemical vapor deposition (MOCVD).

Next, on an upper surface of the multilayer structure 40, a dielectric film made of SiO₂ or the like used as a mask for forming a ridge stripe is formed by, for example, plasma chemical vapor deposition (PCVD) or the like. Lithography is performed to etch the dielectric film except a region of the dielectric film in the ridge stripe with hydrofluoric acid (HF) or the like. Using the dielectric film remaining in the ridge stripe as a mask, the p-type cladding layer 16 is etched partway down to form the ridge stripe by, for example, an Inductive Super Magnetron (ISM) dry etching apparatus, or the like. After that, the dielectric film used as the mask is removed, and a dielectric film made of, for example, SiO₂ or the like is formed on all over the multilayer structure 40. After that, an opening is formed only in the ridge stripe by lithography, and the dielectric film is etched with hydrofluoric acid (HF) or the like. Here, a dielectric film 18 made of SiO₂ is formed as a current blocking layer. Subsequently, Pd/Pt used for a p-side contact electrode 19 is formed by metal deposition. After that, a lift-off method is performed to remove the metal except its portion on an upper surface of the ridge stripe, thereby forming the p-side contact electrode 19. Moreover, a p-side wire electrode 20 is formed on the dielectric film 18 and the p-side contact electrode 19 by metal deposition.

Subsequently, a back surface side of the n-type substrate 10 is polished to reduce its thickness to about 80 μm. Then, an n-side contact electrode 21 is formed by metal deposition. In this way, the multilayer structure 40 as shown in FIG. 1 can be Ruined. Subsequently, using a scribe apparatus, a breaking apparatus, and the like, primary cleaving is carried out along the (101-0) plane of the n-type substrate 10 to form a laser cavity having a length of 800 μm in the present example embodiment. For this purpose, the laser device prior to cleaving is fixed on an adhesive sheet, and a protective sheet is also provided on an upper surface of the laser device to protect the laser device while the cleaving is carried out. Therefore, cavity facets of the laser device (also referred to as laser cavity facets) are between the adhesive sheet and the protective sheet while the primarily cleaving is carried out, and may come into contact with the adhesive sheet and the like after the primarily cleaving is carried out. Hence, there is a possibility that components contained in the adhesive sheet and the like may adhere to the laser cavity facets. Examples of such components contained in the adhesive sheet and the like include a siloxane-based component, and siloxane includes silicon (Si). Therefore, adhesion of Si to the cavity facets may considerably affect long-term reliability of GaN-based nitride light emitting devices. Thus, in the present example embodiment, an adhesive sheet and a protective sheet which contain no Si are used for carrying out the primary cleaving.

Subsequently, descriptions are given of the facet coating process of forming protective films of dielectric films on the cavity facets by using an electron cyclotron resonance (ECR) apparatus.

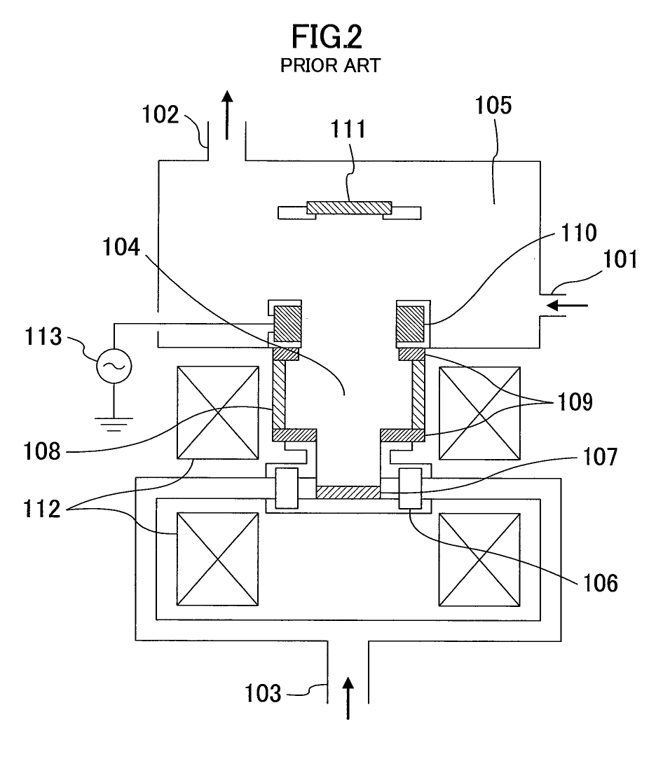

FIG. 2 shows a cross-sectional structure of the ECR apparatus. The ECR apparatus includes a plasma chamber 104 where ECR plasma is generated, a film formation chamber 105, a target material 110, and magnetic coils 112 which are provided around the plasma chamber 104 and produce a magnetic field. The target material 110 is connected to a radio frequency (RF) power source 113 by which the amount of sputtering can be controlled. In the present example embodiment, the target material 110 is a high purity aluminum (Al). Through a microwave introduction port 103, a microwave is introduced, and the microwave is further introduced into the plasma chamber 104 through an introduction window 106. The microwave and the magnetic field produced by the magnetic coils 112 generate the ECR plasma. Moreover, the film formation chamber 105 is evacuated through a gas exhaust port 102. Further, through a gas inlet port 101, argon (Ar) gas, oxygen (O₂) gas, and nitrogen (N₂) gas are introduced into the film formation chamber 105. Furthermore, a laser bar including the laser device after the primary cleaving is carried into the film formation chamber 105 and is arranged on a sample carrier 111 in the film formation chamber 105 such that the cavity facets are irradiated with the ECR plasma. The interior of the plasma chamber 104 is covered with members made of quartz to protect the plasma chamber 104 from the ECR plasma. As the quartz members, an end plate 107, an inner tube 108, and window plates 109 on top and bottom of the inner tube 108 are arranged.

It is preferable that prior to forming the protective films, a plasma cleaning process using Ar gas is performed to carry out a clean-up process on the laser cavity facets. Since performing only plasma irradiation without applying a bias voltage to the target material 110 in the ECR apparatus does not subject the target material 110 to sputtering, the clean-up process can be achieved by generating plasma in a non-biased state. The clean-up process may be carried out using only Ar gas, or using a mixed gas composed of Ar gas and N₂ gas.

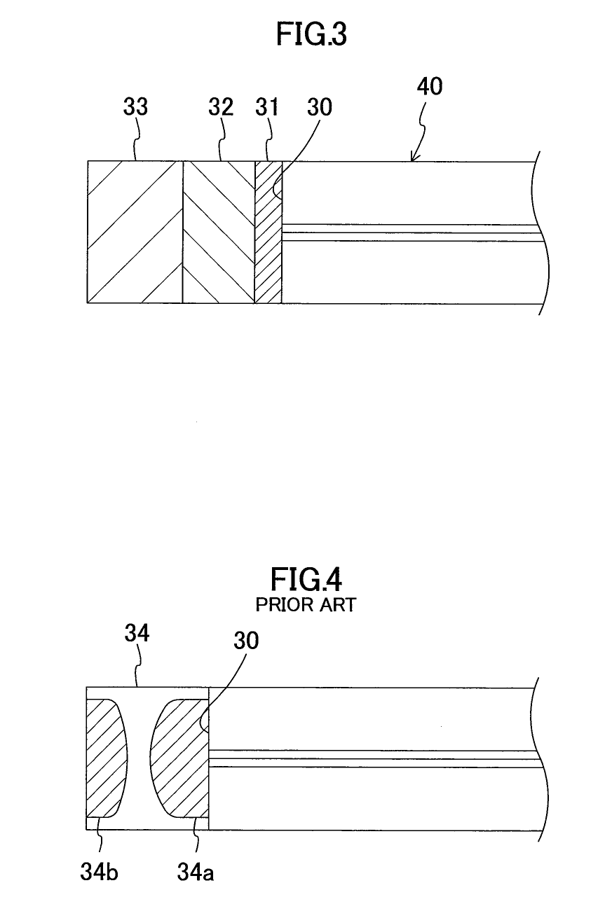

First, protective films on a light emitting facet side will be described with reference to FIG. 3. FIG. 3 is a cross section in a direction parallel to the longitudinal direction of the cavity.

Prior to forming the protective films, the clean-up process is carried out. After that, Ar gas and N₂ gas are introduced into the film formation chamber 105 to generate plasma, and a bias voltage is applied to a target material 110 for depositing an AlN film as a first protective film 31 on a cavity facet 30 of the multilayer structure 40.

Next, after forming the first protective film 31, Ar gas and O₂ gas are introduced into the same film formation chamber 105 for depositing an Al₂O₃ film as a second protective film 32 in a similar manner. Moreover, after forming the second protective film 32, Ar gas and O₂ gas are introduced into another film formation chamber 105 for depositing, in the present example embodiment, a SiO₂ film as a third protective film 33 in a similar manner, where a target material 110 is Si. It should be noted that in the present example embodiment, for forming the AlN film and the Al₂O₃ film respectively as the first protective film 31 and the second protective film 32, Al is used as the target material 110 and processed in an Al target chamber. For forming the SiO₂ film as the third protective film 33, Si is used as the target material 110 and processed in a Si target chamber. Moreover, the third protective film 33 may be formed by magnetron sputtering, where a target material made of SiO₂ is used.

FIG. 4 shows a cross-sectional configuration of a conventional structure in which a protective film 34 made of Al₂O₃ is formed on a cavity facet 30. In this configuration, after long-term operation of a laser device, a crystallization region 34a is formed in a portion of the protective film 34 close to the laser cavity facet. The formed crystallization region 34a may cause deterioration of the laser device. This is because due to the fact that the crystallization temperature of an Al₂O₃ film serving as the protective film 34 is low and the energy of a blue-violet laser beam is high, long-hour irradiation therewith alters the protective film 34 made of Al₂O₃ particularly at a cavity facet section and at an interface between an outermost surface of an coating structure and the atmosphere where the energy is presumed to be high. The crystallization temperature means a temperature at which a film in an amorphous state crystallizes. The higher degree of freedom in strain and the lower strain energy in an amorphous state a film has, the higher the crystallization temperature of the film is. The fact that the crystallization temperature is high means a stable amorphous state. A film of lowest strain energy is a film made of SiO₂. Crystallization temperatures of dielectric films made of representative oxide are shown in Table 1.

TABLE 1

| | Crystallization Temperature |
|---|---|
| Dielectric Film | Tc (° C.) |
| Nb₂O₅ | 500 |
| SiO₂ | ≧1000 |
| ZrO₂ | 400-800 |
| Al₂O₃ | 850 |

In the present example embodiment, a stable AlN film is formed in contact with the cavity facet 30. Therefore, it is possible to suppress alteration in a portion of the Al₂O₃ film close to the cavity facet.

Moreover, the AlN film can suppress permeation of oxygen from the atmosphere through the second protective film 32 and the third protective film 33 to the cavity facet 30. Therefore, it is possible to suppress deterioration of the laser cavity facet and occurrence of the COD during operation of the laser device.

Further, the Al₂O₃ film is formed as the second protective film 32. Since the Al₂O₃ film has a good thermal conductivity, heat concentrating on a light emitting section of the cavity facet 30 can be dissipated through the protective film. Therefore, it is possible to suppress a reduction in facet breaking level during operation of the laser device.

Moreover, the second protective film 32 may be formed of, instead of the Al₂O₃ film, aluminum oxynitride (AlON), niobium oxide (Nb₂O₃), zirconium dioxide (ZrO₂), titanium dioxide (TiO₂), tantalum pentoxide (Ta₂O₅), or the like, and is further desirably made of a material having a high thermal conductivity.

Moreover, an AlO₂ film is characterized in that the direction of stress of the AlO₂ film is different from that of the AlN film. If the second protective film 32 is formed of a SiO₂ film, a tensile stress results which is in the same direction as that of AlN forming the first protective film 31. As a result, a stress applied to the facet protective films increases, that is, a stress applied to the laser cavity facet 30 increases, thereby rapidly causing deterioration during operation of the laser device. Therefore, it is desirable that a material having a compressive stress is used for the second protective film 32.

Furthermore, the SiO₂ film is formed as the third protective film 33. Therefore, it is possible to solve the problem that in the case of the protective film 34 made of Al₂O₃ on the cavity facet 30 as shown in FIG. 4, a crystallization region 34b is formed in a portion of the protective film 34 close to an interface between the atmosphere and an outermost surface of the protective film 34 after long-hour operation of the laser device.

It is contemplated that this problem is caused because due to the fact that the crystallization temperature of the Al₂O₃ film is low and the energy of a blue-violet laser beam is high, long-hour irradiation therewith alters the protective film made of Al₂O₃ particularly at the cavity facet section and at an interface between an outermost surface of the facet protective film and the atmosphere where the energy is high. Forming a SiO₂ film of high crystallization temperature as the third protective film 33 as shown in FIG. 3 can suppress alteration of the protective film made of Al₂O₃.

Moreover, as shown in FIG. 3, in the present example embodiment, after forming the first protective film 31 made of AlN, the Al₂O₃ film is formed as the second protective film 32, and then the third protective film 33 made of SiO₂ is formed. Therefore, the facet reflectance of the light emitting section can be controlled by the thicknesses respectively of the first protective film 31, the second protective film 32, and the third protective film 33. FIG. 5 shows a result of evaluation of variations in facet reflectance with respect to variations in film thickness. The combination of facet protective films according to the present example embodiment can achieve a facet coating structure in which the variations in facet reflectance with respect to the variations in film thickness are small as shown in FIG. 5. Therefore, in the present example embodiment, the reflectance with respect to a laser beam is set to less than 18%, and preferably to 12%. Especially, the reflectance at a cavity facet of an emitting section is desirably set to be greater than or equal to 8% and less than 13%.

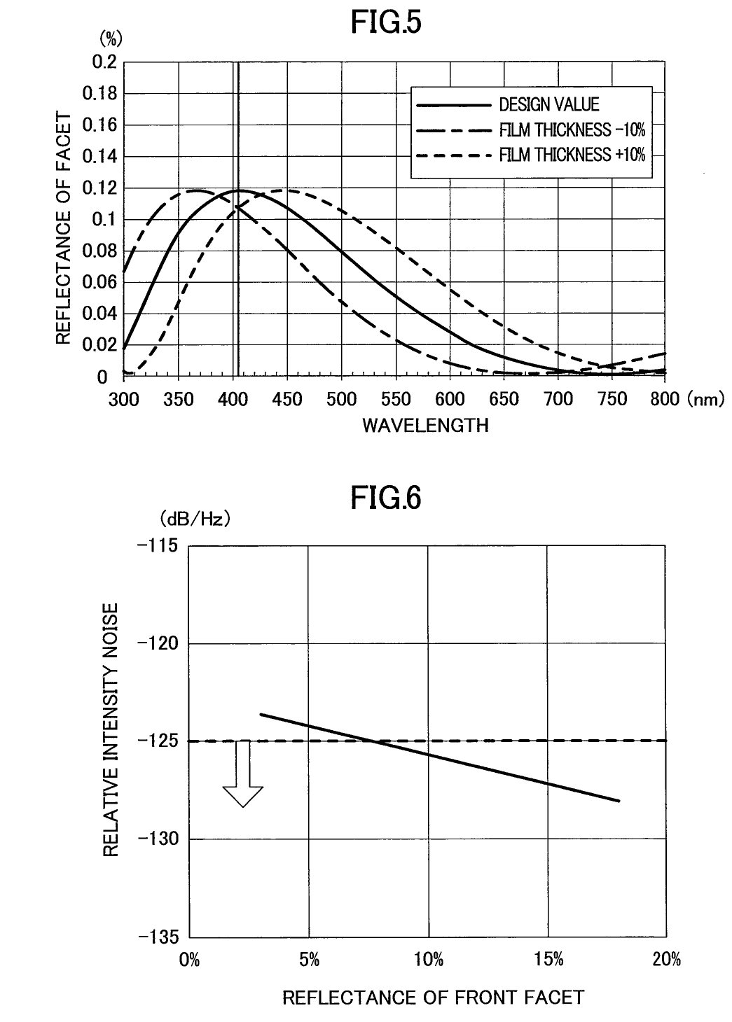

If the reflectance is lowered, the problem of external feedback noise for use in optical pickup devices may arise. FIG. 6 shows the dependence of Relative Intensity Noise (RIN) on the reflectance of a front facet. Depending on designs of optical pickup devices, it is required that from the viewpoint of the external feedback noise, the RIN is −125 dB/Hz or lower as shown in FIG. 6, and thus the reflectance is desirably 8% or higher. Moreover, if the reflectance is raised, there are many advantages such as a reduction in threshold current value and the like, but the optical density of the light emitting section increases, making it difficult to satisfy a high COD level essential for a high output operation.

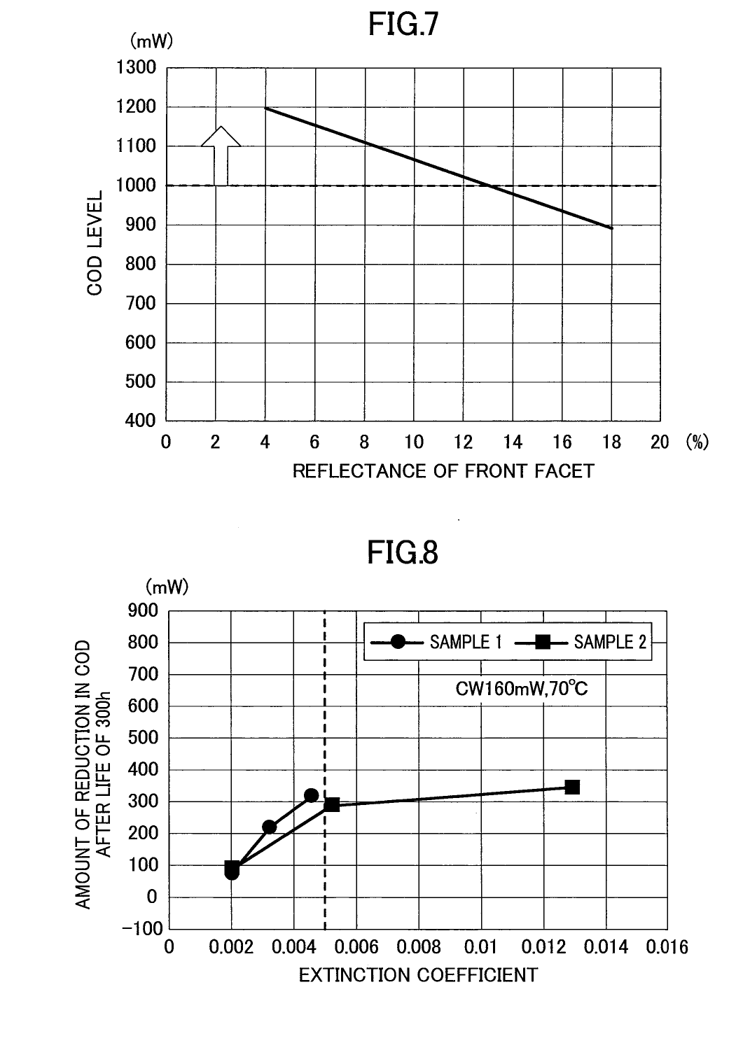

FIG. 7 shows the dependence of the COD level on the reflectance of the front facet. As shown in FIG. 7, to realize that the COD level is, for example, 1000 mW, the reflectance is desirably less than 13%.

Moreover, the thickness of the first protective film 31 made of AlN is desirably set to be greater than or equal to 4 nm and less than or equal to 20 nm. This is because forming the AlN film to have a thickness of 4 nm or more makes it possible to suppress variations in oxygen permeability of the cavity facet caused by variations in thickness of the AlN film, and particularly to suppress variations in the COD level. This is also because forming the AlN film to have a thickness of 20 nm or less makes it possible to reduce absorption of a laser beam by the AlN film due to its extinction coefficient, and to achieve a less reduction in the COD level during operation of the laser device compared to the case of a large film thickness.

Moreover, the extinction coefficient of the first protective film 31 made of AlN is desirably 0.005 or less. This is because setting the extinction coefficient to 0.005 or less makes it possible to reduce the absorption of light by the facet protective film on the light emitting section.

FIG. 8 shows a correlation diagram of the extinction coefficient and the COD level of the present example embodiment. As shown in FIG. 8, the extinction coefficient is set to 0.005 or less. This makes it possible to suppress a reduction in the COD level particularly during operation of the laser device to 300 mW or less. Here, a laser operating condition is such that the continuous wave (CW) output is 160 mW, the operating temperature is 70° C., and the operating time is 300 hours.

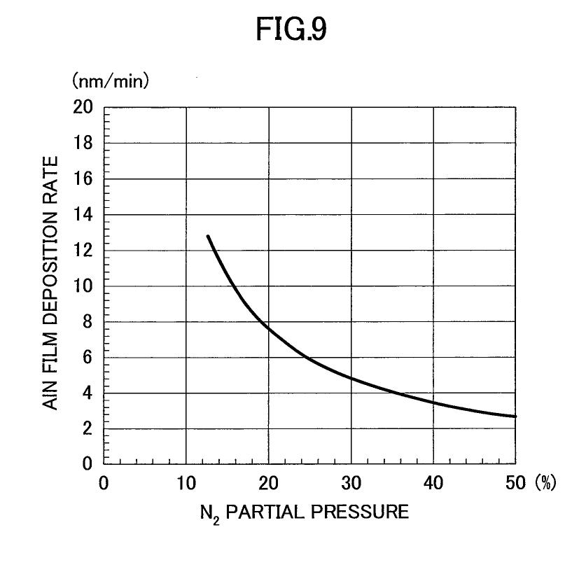

FIG. 9 shows a correlation diagram of the N₂ partial pressure and the film deposition rate of an AlN film according to the present example embodiment. The AlN film serving as a first film is deposited with the N₂ partial pressure being high as shown in FIG. 9, thereby achieving a reduction in film deposition rate. When the film deposition rate is reduced, a state of a crystallographic axis of the cavity facet has no influence, but a growth mode in the directions of a crystallographic axis along which the AlN film can easily grow becomes dominant. Therefore, it is possible to obtain a crystal film oriented in the direction of the C-axis of crystallographic axes that differs by 90 degrees from the crystallographic axis of the cavity facet of the nitride semiconductor, and thus a film configuration of higher density can be realized. A protective film close to the light emitting facet is formed of an AlN crystal film oriented in the direction of the C-axis. In this case, the bonding length between atoms constituting AlN crystals is short, and thus the protective film is dense. Therefore, it is possible to further suppress the permeation of oxygen to an interface between the cavity facet and the protective film during laser operation.

Moreover, at the same tine, since the N₂ partial pressure is high and the Ar partial pressure is low in this film deposition condition, a plasma damage caused by Ar gas within the plasma chamber 104 is suppressed. Therefore, it is possible to suppress etching-caused abrasion of the members made of quartz (i.e., the end plate 107, the inner tube 108, and the window plate 109). The abrasion is caused because the mass of Ar is comparatively large, and thus the quartz members are exposed to Ar plasma and etching of the quartz members advances. It is possible to suppress that Si and O which are main components of the quartz members adhere to an interface between the laser cavity facet 30 and the protective film.

In this way, absorption of a laser beam at the interface due to, for example, formation of SiOₓ is suppressed, so that heat generation and deterioration of the facet can be suppressed.

Next, a reflective film on a light reflection facet side will be described. In the same manner as for the light emitting facet side, a clean-up process is carried out prior to forming the reflective film. After that, Ar gas and O₂ gas are introduced into the film formation chamber 105 to deposit a first film, for example, an Al₂O₃ film. Subsequently, in another film formation chamber, a reflective film composed of a multilayer film made of, for example, SiO₂ and ZrO₂ is formed such that an outermost surface of the multilayer film ends with, for example, a ZrO₂ film. The thicknesses respectively of Al₂O₃, SiO₂, and ZrO₂ are adjusted such that the reflectance with respect to a laser beam is 90% or higher.

Subsequently, the laser bar is subjected to secondary cleaving to obtain a laser chip.

Next, a mounting process will be described. The laser chip described above is mounted on a submount made of, for example, AlN or SiC and having a solder material, and is then mounted on a stem. Subsequently, an Au wire for supplying a current is connected to the p-side wire electrode 20 and to a wire electrode of the submount which is connected with the n-side contact electrode 21. Finally, to isolate the laser chip from the outside air, a cap provided with a window from which the laser beam is drawn is fusion-bonded to the laser chip. In this way, the laser device can be realized.

A nitride light emitting device fabricated according to the present example embodiment was operated at a room temperature. As a result, it was confirmed that the threshold current was 30 mA, the slope efficiency was 1.5 W/A, the oscillation wavelength was 405 nm, and continuous oscillation was performed. Moreover, a reliability test was conducted under a high-temperature and high-power condition (70° C., 160 mW), with the nitride light emitting device being in CW operation. As a result, the nitride light emitting device was able to stably operate for 1000 hours or longer.

As described above, since the structure of the protective films on a laser cavity facet is an AlN/Al₂O₃/SiO₂ structure, an outermost surface thereof is made of SiO₂ of high crystallization temperature. Therefore, it is possible to suppress crystallization of a protective film made of Al₂O₃, and thus a stable device characteristic after long-hour laser operation can be realized. Moreover, an AlN film formed at an interface to the laser cavity facet can suppress oxygen permeation to the laser cavity facet. Therefore, it is possible to reduce light absorption, and to suppress deterioration of the laser cavity facet and occurrence of the COD at a low level. Moreover, since stress balance is good, it is possible to suppress rapid deterioration during operation of the laser device caused by, for example, application of a strong compressive stress.

In this way, it is possible to suppress crystallization of a facet protective film. Moreover, increasing the COD level and suppressing a decrease in the COD level during laser operation can dramatically improve the reliability and the durability.

### Second Example Embodiment

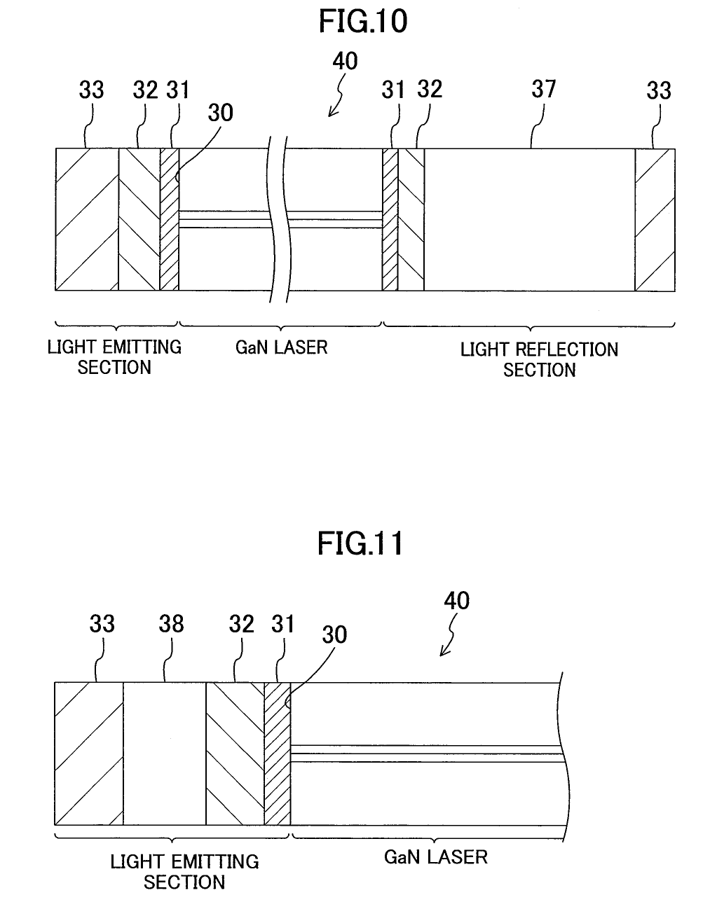

Hereinafter, a second example embodiment will be described with reference to FIG. 10.

FIG. 10 shows a cross-sectional configuration in a direction parallel to the longitudinal direction of a cavity of a nitride semiconductor light emitting device according to the second example embodiment.

The present example embodiment is different from the first example embodiment only in the process of forming protective films on a light reflection facet side, and thus the description of the other processes is omitted.

A method for forming the protective films on the light reflection facet side will be described.

In the same manner as for forming the protective films on the light emitting facet side, a clean-up process is carried out prior to forming the protective films on the light reflection facet side. After that, Ar gas and N₂ gas are introduced into a film formation chamber 105 to deposit an AlN film 31 as a first protective film.

Subsequently, Ar gas and O₂ gas are introduced into the same film formation chamber to form an Al₂O₃ film 32 as a second protective film in the film formation chamber. Moreover, in another film formation chamber, a multilayer film 37 composed of SiO₂ and ZrO₂ deposited with six periods and also a SiO₂ film 33 on an outermost surface are formed as a third protective film to produce a light reflection facet. The thicknesses of respective films are adjusted such that the reflectance with respect to a laser beam is 90% or higher.

As on the light emitting side, the first protective film is formed of the AlN film 31, which makes it possible to suppress crystallization of a portion of the Al₂O₃ film 32 serving as the second protective film close to a cavity facet, and to suppress permeation of oxygen to the cavity facet. Therefore, it is possible to prevent deterioration which occurs on the cavity facet on the light reflection facet side during operation of the laser device. Moreover, the SiO₂ film 33 of high crystallization temperature is formed on the outermost surface, which makes it possible to prevent the crystallization at an interface to the atmosphere, thereby allowing stable operation of the laser device.

### Third Example Embodiment

Hereinafter, a third example embodiment will be described with reference to FIG. 11.

FIG. 11 shows a cross-sectional configuration in a direction parallel to the longitudinal direction of a cavity of a nitride semiconductor light emitting device according to the third example embodiment.

The present example embodiment is different from the first example embodiment only in the process of forming protective films on a light emitting facet side after the primary cleaving process, and thus the description of the other processes is omitted.

A method for forming the protective films on the light emitting facet side will be described.

First, a clean-up process prior to forming the protective films is carried out. After that, Ar gas and N₂ gas are introduced into a film formation chamber 105 to generate plasma, and a bias voltage is applied to a target material 110 to deposit an AlN film as a first protective film 31 on a laser cavity facet 30.

Next, after forming the first protective film 31, Ar gas and O₂ gas are introduced in the same film formation chamber 105 to deposit an Al₂O₃ film as a second protective film 32 in a similar manner. Moreover, after forming the second protective film 32, a SiO₂ film/a Al₂O₃ film are sequentially formed as a third protective film 38 in a similar manner. After that, as an outermost surface film 33 of the third protective film, a SiO₂ film of high crystallization temperature is deposited.

It should be noted that in the present example embodiment, for forming the AlN film as the first protective film, and the Al₂O₃ films as the second protective film and the third protective film, Al is used as the target material 110 and processed in an Al target chamber. For forming the SiO₂ film as the outermost surface of the third protective film, Si is used as the target material 110 and processed in a Si target chamber. Alternatively, the third protective film may be formed by magnetron sputtering, where a target material made of SiO₂ is used.

Moreover, the structure of the third protective film, e.g., the SiO₂ film/the Al₂O₃ film, can be selected from the viewpoint of reflectance, thermal conductivity, and stress. Therefore, an AlN film, an Al₂O₃ film, a SiN film, and an AlON film, or a Nb₂O₅ film, a ZrO₂ film, a SiO₂ film, a TiO₂ film, and a Ta₂O₅ film, or the like may be possible. Moreover, a two-layer structure or a more-than-two-layer structure may be possible. Moreover, among the materials mentioned above, materials of high thermal conductivity are desirable.

Forming the AlN film as the first protective film 31 can solve the problem that in the conventional structure of FIG. 4 having the Al₂O₃ protective film 34 formed on the laser cavity facet 30, the crystallization region 34a is formed in the portion of the protective film 34 made of Al₂O₃ close to the laser cavity facet after long-hour operation of the laser device.

It is contemplated that this problem is caused because due to the fact that the crystallization temperature of the Al₂O₃ film serving as the second protective film is low and the energy of a blue-violet laser beam is high, long-hour irradiation therewith alters portions of the Al₂O₃ protective film particularly at the cavity facet section and at the interface between the outermost surface of the coating structure and the atmosphere where the energy is presumed to be high.

Moreover, permeation of oxygen from the atmosphere through the second protective film 32 and the third protective film 33 to the cavity facet can be suppressed by forming the AlN film. Therefore, it is possible to suppress deterioration of the laser cavity facet and the occurrence of the COD at a low level during operation of the laser device.

Further, the Al₂O₃ film is formed as the second protective film 32. Since Al₂O₃ has a high thermal conductivity, heat concentrating on the laser cavity facet 30 can be dissipated through the facet protective film. Therefore, it is possible to suppress a reduction in facet breaking level during operation of the laser device.

Furthermore, the SiO₂ film is formed as the outermost surface film 33 of the third protective film. Therefore, it is possible to solve the problem that in the case of the protective film 34 made of Al₂O₃ on the laser cavity facet 30 as shown in FIG. 4, the crystallization region 34b is formed in the portion of the protective film 34 close to the interface between the atmosphere and the outermost surface of the protective film 34 after long-hour operation of the laser device.

It is contemplated that this problem is caused because due to the fact that the crystallization temperature of Al₂O₃ is low and the energy of a blue-violet laser beam is high as in the above mentioned case, long-hour irradiation therewith alters the protective film made of Al₂O₃ particularly at the cavity facet section and at the interface between the outermost surface of the coating structure and the atmosphere where the energy is high. Forming a SiO₂ film of high crystallization temperature as the outermost surface film 33 of the third protective film as shown in FIG. 11 can suppress alteration of the protective film made of Al₂O₃.

Moreover, as shown in FIG. 11, in the present example embodiment, after forming the first protective film 31 made of AlN, the Al₂O₃ film is formed as the second protective film 32, a multilayer structure including a plurality of films is further formed as the third protective film 38, and the SiO₂ film is further formed as a surface layer 33 of the third protective film. Therefore, the degree of freedom in design particularly with respect to the reflectance is largely increased compared to the case where the third protective film is made of only SiO₂, which enables the reflectance to be set freely, and desirable laser device characteristics to be realized.

It should be noted that for the first example embodiment through the third example embodiment, the following can be said.

The p-side contact electrode 19 is desirably made of a material capable of reducing contact resistance against the p-type contact layer 17 in order to reduce an operating voltage and having a good adhesion. In the present example embodiment, Pd/Pt is used for the p-side contact electrode 19. Alternatively, a combination of nickel (Ni)/Au, Ni/Pt/Au, Pd, Pd/molybdenum (Mo), Pd/Au, or the like has a low contact resistance and a good adhesion, and thus the similar advantage can be obtained.

In the present example embodiments, a GaN substrate is shown as an example. However, the similar advantage can be obtained from substrates based on other materials, for example, a sapphire substrate, an Epitaxial Lateral Over Growth (ELOG) substrate or an Air-Bridged Lateral Epitaxial Growth (ABLEG) substrate on a sapphire substrate, ELOG on a GaN substrate, a GaN template substrate with sapphire being removed by laser lift off, a silicon carbide (SiC) substrate, a Si substrate, a gallium arsenide (GaAs) substrate, an indium phosphide (InP) substrate, a NGO (i.e., NbGaO₃) substrate, a LGO (i.e., LiGaO₃) substrate, or the like.

In the present example embodiments, the nitride semiconductor light emitting device is described as an example. However, the present example embodiments are applicable to semiconductor light emitting devices based on other materials, for example, AlGaInP-based, AlGaAs-based, or InGaAsP-based semiconductor light emitting devices.

As described above, in the nitride semiconductor light emitting device according to the present disclosure, it is possible to suppress crystallization of a second protective film containing aluminum of low crystallization temperature, and to suppress permeation of oxygen to a cavity facet of a light emitting section. This makes it possible to suppress deterioration of a laser cavity facet and the occurrence of the COD at a low level, so that long-term reliability during a high-power operation of the laser device can be obtained. The nitride semiconductor light emitting device according to the present disclosure is useful particularly for a nitride semiconductor light emitting device or the like having a protective film provided on a cavity facet.

What is claimed is:

1. A nitride semiconductor light emitting device comprising:
a multilayer structure composed of a plurality of nitride semiconductor layers including a light emitting layer where the multilayer structure has cavity facets facing each other; and
a plurality of protective films made of dielectric materials on at least one of the cavity facets, wherein
among the plurality of protective films, a first protective film in contact with the cavity facet is made of a material containing no oxygen,
a second protective film on a surface of the first protective film opposite to the cavity facet is made of a material containing aluminum lower in crystallization temperature than the first protective film, and
a third protective film on a surface of the second protective film opposite to the first protective film has an exposed surface and is made of a material higher in crystallization temperature than the second protective film.

2. The nitride semiconductor light emitting device of claim 1, wherein the third protective film is composed of two or more films respectively made of different materials.

3. The nitride semiconductor light emitting device of claim 1, wherein a crystallization temperature of a surface portion of the third protective film is 1000° C. or higher.

4. The nitride semiconductor light emitting device of claim 1, wherein the plurality of protective films is formed on both of the cavity facets.

5. The nitride semiconductor light emitting device of claim 1, wherein the third protective film is made of silicon dioxide.

6. The nitride semiconductor light emitting device of claim 1, wherein the second protective film is made of aluminum oxide.

7. The nitride semiconductor light emitting device of claim 1, wherein the first protective film is made of aluminum nitride.

8. The nitride semiconductor light emitting device of claim 7, wherein the first protective film has a crystal plane whose crystallographic axes form an angle of 90 degrees with crystallographic axes of a crystal plane of the cavity facet having the first protective film formed thereon.

9. The nitride semiconductor light emitting device of claim 7, wherein an extinction coefficient of the aluminum nitride is 0.005 or less in an oscillation wavelength band of emitted light output from the light emitting layer.

10. The nitride semiconductor light emitting device of claim 7, wherein a film thickness of the aluminum nitride is greater than or equal to 4 nm and less than or equal to 20 nm.

11. The nitride semiconductor light emitting device of claim 1, wherein the reflectance of the plurality of protective films is less than 18%.

12. The nitride semiconductor light emitting device of claim 1, wherein the reflectance of the plurality of protective films is greater than or equal to 8% and less than 13%.
